(19) United States
(12) Patent Application Publication
(10) Pub. No.: US 2009/0098849 A1
(43) Pub. Date: Apr. 16, 2009

(54) Hybrid receiver provided with adaptive front and back terminals

(76) Inventors: Thomas Adam, Bad Urach (DE); Wolfgang Sautter, Reutlingen (DE); Christian Schwarz, Bempflingen (DE); Robert Thomas, Wolfschlugen (DE)

Correspondence Address: K.F. ROSS P.C., 5683 RIVERDALE AVENUE, SUITE 203 BOX 900, BRONX, NY, 10471-0900, US

(21) Appl. No.: 11/990,611

(22) PCT Filed: Aug. 15, 2006
(86) PCT No.: PCT/EP2006/008045

§ 371 Date: Mar. 4, 2008

(30) Foreign Application Priority Data
Aug. 16, 2005 (DE) 10200038944.9

(51) Int. Cl. H05K 11/02

(52) U.S. Cl. 455/345

(57) ABSTRACT

The invention relates to a receiver device for the mobile reception of high-frequency signals of different services in motor vehicles comprising at least one receiver unit for receiving and processing country specific services and a communications unit for connecting the receiver device to the motor vehicle communications bus.

The invention relates to a receiver for the mobile reception of high-frequency signals (HF signals) from various services in vehicles.

Today, in various countries throughout the world, different analog and digital TV standards are used. One example is the digital terrestrial service DVB-T, which is known in Europe, and the digital terrestrial standard ISDB-T, which is used in Japan. Other standards, for example, DMB-T, DVB-H, or ATSC, are already in use or their infrastructure is still being built up. These different standards require a flexible concept for receivers and for their connection to existing communication structures in a vehicle.

Today, most vehicle manufacturers use one or more of the essentially standardized busses such as, for example, IEE1394, CAN, or MOST, for controlling multimedia devices. However, every vehicle manufacturer also uses its own proprietary functions on the bus. Very often, this also requires that the hardware and software of the communication units be adapted to the specifications of the vehicle manufacturer.

The object of the invention is to provide a receiver for the mobile reception of high-frequency signals from various services in vehicles that reduces development expense and allows the adaptation of new services to existing communication structures in the vehicle or vice versa.

This object is attained by the features of claim 1.

According to the invention, provision has been made for the receiver to have at least one receiving unit for receiving and processing country-specific services as well as a communication unit for connecting the receiver to a communication bus of the vehicle, with the receiving unit and the communication unit being connected to one another in an exchangeable fashion for the purpose of signal transmission. The receiver is thus divided in an advantageous fashion into two separate units that communicate with one another and that may be separately developed and optimized with regard to their respective functions. If, for example, the communication bus and its topology remain unchanged but new, country-specific services (such as radio or television programs, for example) must be processed, it is only necessary for the associated receiving unit to be correspondingly redeveloped or adapted, while the communication device is able to remain unchanged. Inversely, this means that when the country-specific services to be received and processed remain unchanged but there is a new topology for the communication bus in the vehicle, only the communication unit need be adapted to the new topology, while the connection (interface) to the associated receiving unit can remain unchanged.

The idea underlying this fact is therefore the division of future generations of receivers into two fields, one configured for connection to customer-specific communications structure and the other configured for connection to the TV and radio services available in a given country. Up to now, currently known concepts have not been configured to take this state of affairs into account. The development of a new receiver for a certain standard in a certain country requires at the same time its redevelopment and integration into the vehicles of the automotive industry with all of the financial disadvantages associated therewith.

Going forward, the receiving unit will be referred to as the front end and the communication unit will be referred to as the back end.

In a further development of the invention, the communication unit has means that are structured for adapting the topology of the communication unit to the topology of the communication bus of the vehicle. In this manner, communication is conducted between the receiver overall and the communication bus of the vehicle, with the receiver unit for receiving and processing country-specific services being unaffected thereby. This means is that, in the case of changes to the topology of the communication bus of the vehicle, only the corresponding means (hardware and/or software) of the communication unit need to be adapted to the new topology of the communication bus. This simplifies and accelerates the development of a new receiver and, in addition, reduces its costs because only the means and/or the function of the means of the communication unit need be adapted to the new topology of the communication bus.

The front end is characterized in that it has one or more receiving units for one or more analog and/or digital standards. For one digital service, DVB-T, for example, these units are tuners, demodulators, and the associated MPEG decoder. Application-specific diagnostic jobs are also performed by the front end to the greatest extent possible.

The back end is characterized in that it has the specific communication units for the customer-specific bus topologies (for example, IEE1394, MOST, and/or CAN). The back end also includes the network component with the connection to the vehicle's power supply. Moreover, the back end assumes the diagnostic jobs that are necessary but are to a large extent independent of the receiver standard.

The physical separation into back end and front end is accomplished by means of two separate circuit boards that are connected via defined interfaces. By the judicious placement of interfaces on the back end and front end, it is possible for many different front ends with different receiver standards to be connected to the back end. This shows the possible savings potential for the automotive industry. Only application-specific front ends will be developed for new services. The back end will be developed only once per automobile manufacturer and once per bus architecture used. Reuse of hardware and software will considerably accelerate the development of receivers for new standards. Moreover, a considerable increase in quality for the development of future front ends is to be expected due to the reuse of hardware and software that has already been proven and tested.

In this connection, the back end is set up in such a way that, dependent upon the front end and communications standard used, variant assemblies may be used for the purpose of cost optimization.

Illustrated embodiments of the invention are described below in a non-limiting fashion with reference to the two drawings.

Both figures show the basic distribution of the receiver overall with one or more receiver chains in the receiving unit (front end) and the communication unit (back end). The front end shows antennas in a manner that is known per se that are connected to one or more receiver modules, with the receiver module being able to receive the country specific services (such as ISDB-T, for example). In general, this means that the front end has one or more receiver chains with tuners, demodulators, optionally MPEG decoders, and the like. The back end is physically separate from the above with its respective elements or components that, like the elements and components of the front end, are mounted on an independent circuit board. Signal transmission from the front end to the back end (and, optionally, vice versa, as necessary) occurs via a correspondingly configured interface, by way of which the digital and/or analog radio, television, video, or audio signals may be transmitted, in the same manner as control signals, diagnostic signals, and power supply. For this purpose, the back end has a network component for its own power supply as well as one for power supply to the front end.

Alternatively, the network component may also be in the front end, with the respective network component also being supplied with power from the vehicle's power supply.

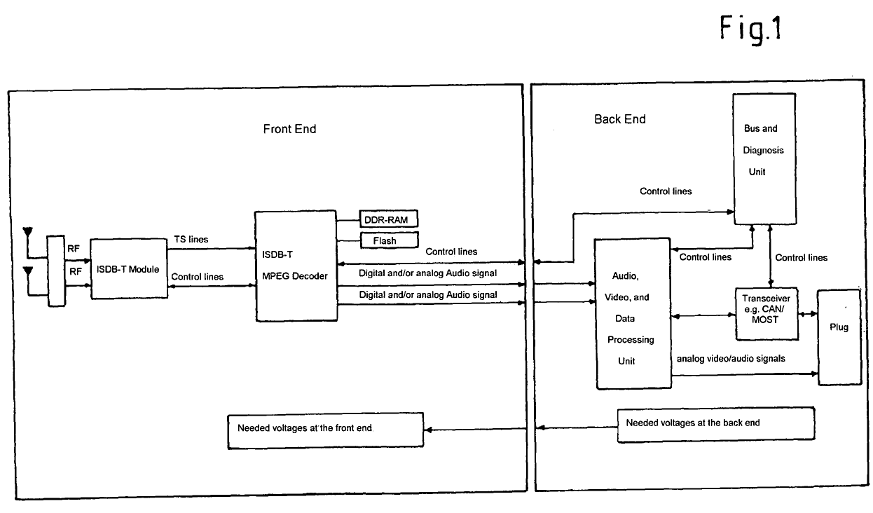

FIG. 1 shows a block diagram with one front end and one back end for use in ISDB-T devices.

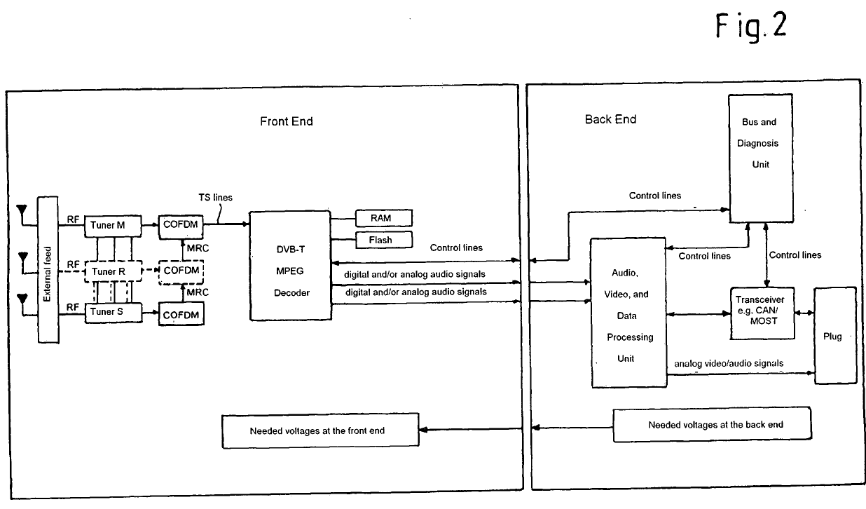

FIG. 2 again shows precisely the same back end with a front end for the digital terrestrial standard DVB-T. Other block diagrams for other TV standards are therefore quite conceivable. Therefore, its use in a specific vehicle of a vehicle manufacturer in various countries throughout the world with various receiver standards is quite conceivable as well.

The circuit boards with the electrical and electronic components for performing the function of the respective unit are either mounted together in one housing at one single installation site in the vehicle or, alternatively, may be mounted in their own housings at the same installation site or at installation sites that are separate from one another. If the front end and back end are mounted at different installation sites, the transmission of the signals and/or power supply occurs via at least one appropriate cable that is provided for this purpose, with it being particularly advantageous for the front end to be mounted near the antenna while the back end, for example, is mounted at the installation location of a central controller of the vehicle. Thus, for example, it is also conceivable for the back end to be integrated into the central controller or into one of several controllers of the vehicle.

In summary, therefore, the present invention offers the advantage that the means for receiving and processing the high-frequency signals and by way of which the country-specific services are emitted and received are combined in a first unit, namely the receiving unit (front end). The second unit, which is necessary for signal processing and communication with a communication bus of the vehicle, is mounted both functionally and spatially separate from it. In the case of changes to the reception of country-specific services, this allows the front end to be either modified, for example, by a software update, or completely exchanged without the back end being affected. On the other hand, if the same country-specific services need to be received and processed but the entire receiver needs to be installed in a new vehicle with a new communications structure, it is sufficient to adapt the back end to correspond to the new communications structure (topology of the communication bus of the vehicle) without needing to make changes to the front end.

In conclusion, for the sake of completeness, it must be mentioned that the high-frequency signals with the country-specific services received by the antenna, in particular multiple antennas, are received and processed via one or more receiver chains in the receiving unit and processed in the communication unit by the processing unit present there, so as to then transmit them via the interfaces of the communication bus to the appropriate devices in the vehicle for further processing. These devices, for example, play radio programs, show television programs, or allow the exchange of data. Moreover, it is conceivable in such a case for the receiver chain of the receiver to be used not only unidirectionally, but also in reverse. This means that the present receiver is not only able to receive signals, but also to transmit them.

1. A receiver for the mobile reception of high-frequency signals from various services in vehicles wherein the receiver has at least one receiving unit for receiving and processing country-specific services as well as a communication unit for connecting the receiver to a communication bus of the vehicle, the receiving unit and the communication unit being connected together in an exchangeable manner for the purpose of transferring signals.

2. The receiver according to claim 1 wherein the receiving unit is set up for receiving and processing at least one service that is transmitted and received via analog or digital high-frequency signals and, for this purpose, has at least one antenna, at least one tuner, and at least one decoder for processing signals it receives.

3. The receiver according to claim 1 wherein the communication unit has means for adapting the topology of the communication unit to the topology of the communication bus of the vehicle by a change to the hardware or the software.

4. The receiver according to claim 1 wherein the receiver unit and the communication unit are physically separate from one another and the electrical and electronic components for performing the functions of each unit are mounted on a respective single circuit board and interfaces are provided for connecting the receiving unit and the communication unit to one another and connecting the communication unit to the communication bus of the vehicle.

5. The receiver according to claim 1 wherein one of the communication unit and the receiving unit has a network component for its own power and for supplying power to the other of the receiving unit and the communication unit.

6. The receiver according to claim 1 wherein the communication unit has at least one processing unit for audio, video, or data signals.

7. The receiver according to claim 1 wherein the communication unit has at least one diagnostic unit for monitoring the function of the receiving unit or the function of the communication bus of the vehicle.

8. The receiver according to claim 1 wherein the connection between the communication unit and the communication bus of the vehicle is set up for conducting a software update initiating from a central controller of the vehicle.

9. The receiver according to claim 8 wherein the communication unit has a separate interface to which the controller may be connected for conducting a software update.
